(19) United States
(12) Patent Application Publication
(10) Pub. No.: US 2024/0194607 A1
(43) Pub. Date: Jun. 13, 2024

(54) SEMICONDUCTOR DEVICE AND MANUFACTURING METHOD THEREOF, MEMORY AND MEMORY SYSTEM

(71) Applicant: Yangtze Memory Technologies Co., Ltd., Wuhan (CN)

(72) Inventors: Qiangwei Zhang, Wuhan (CN); Bin Yuan, Wuhan (CN); Zongke Xu, Wuhan (CN); Yali Guo, Wuhan (CN); Wei Xu, Wuhan (CN); Lei Xue, Wuhan (CN); Zongliang Huo, Wuhan (CN)

(21) Appl. No.: 18/148,751

(22) Filed: Dec. 30, 2022

(30) Foreign Application Priority Data
Dec. 9, 2022 (CN) 202211586197.2

(51) Int. Cl. H01L 23/535; H10B 43/27

(52) U.S. Cl. CPC H01L 23/535; H01L 27/11582

(57) ABSTRACT

A semiconductor device and a manufacturing method thereof, a memory and a memory system are disclosed. The method includes: providing a substrate and stacked layers on the substrate, the stacked layers comprising interlayer sacrificial layers and interlayer insulating layers which are alternately stacked; removing part of the interlayer sacrificial layer to form a gate gap; sequentially forming a protection layer and a gate structure in the gate gap; forming a contact hole extending from a side of the stacked layers facing away from the substrate into a remaining interlayer sacrificial layer and exposing the protection layer; removing the protection layer exposed in the contact hole to expose the gate structure; forming a contact structure in the contact hole in such a way that the contact structure is connected with the gate structure.

### CROSS REFERENCE TO RELATED APPLICATION

This application claims priority to and the benefit of Chinese Patent Application No. 202211586197.2, filed on Dec. 9, 2022, which is hereby incorporated by reference in its entirety.

### TECHNICAL FIELD

The present disclosure relates to the technical field of semiconductors, and in particular to a semiconductor device and a manufacturing method thereof, a memory and a memory system.

### BACKGROUND

As the number of stacked layers of a memory increases, the manufacturing process of the memory becomes increasingly difficult. How to manufacture a memory with improved performance is a problem that needs to be solved currently.

### BRIEF DESCRIPTION OF THE DRAWINGS

In order to illustrate technical solutions in the examples or the prior art more clearly, the drawings needed in the description of the examples or the prior art will be briefly introduced below. Obviously, the drawings in the following description only show some examples of the present disclosure, and for those of ordinary skill in the art, other drawings can be obtained according to these drawings without creative effort.

FIG. 1a to FIG. 1d are schematic structural diagrams of a manufacturing method of a semiconductor device provided by some examples;

FIG. 2 is a flowchart of a manufacturing method of a semiconductor device provided by an example of the present disclosure;

FIG. 3a to FIG. 3i are schematic structural diagrams of a manufacturing method of a semiconductor device provided by an example of the present disclosure;

FIG. 4 is a schematic structural diagram of a semiconductor device provided by an example of the present disclosure;

FIG. 5 is a schematic structural diagram of a memory provided by an example of the present disclosure; and

FIG. 6 is a schematic structural diagram of a memory system provided by an example of the present disclosure.

### DETAILED DESCRIPTION

The specific structural and functional details disclosed herein are merely representative and are for the purpose of describing the example examples of the present disclosure. However, the present disclosure can be embodied in many alternative forms, and should not be construed as being limited only to the examples set forth here.

In the description of the present disclosure, it should be understood that, orientational or positional relationships indicated by terms such as “central”, “lateral”, “upper”, “lower”, “left”, “right”, “vertical”, “horizontal”, “top”, “bottom”, “inside”, “outside” and the like are the orientational or positional relationships shown on the basis of the drawings, and are merely for the convenience of describing the present disclosure and simplifying the description, but do not indicate or imply that the referred apparatuses or elements must have specific orientations or must be constructed and operated in specific orientations, and thus cannot be construed as limitations to the present disclosure. In addition, the terms “first” and “second” are used for descriptive purposes only and cannot be understood as indicating or implying relative importance or implicitly indicating the number of the indicated technical features. Thus, the features defined with “first” and “second” may explicitly or implicitly include one or more of the features. In the description of the present disclosure, unless otherwise stated, “a plurality of” means two or more. Furthermore, the term “comprise” and any variations thereof are intended to cover non-exclusive inclusion.

In the description of the present disclosure, it needs to be noted that the terms “joining”, “connection” should be interpreted in a broad sense unless otherwise expressly specified or defined, and may be, for example, a fixed connection, a detachable connection, or an integral connection; may also be a mechanical connection, or an electric connections; may also be a direct connection, or an indirect connection via intervening medium structure; may also be inner communications of two elements. The specific meaning of the above terms in the present disclosure may be understood by those of ordinary skill in the art according to particular circumstances.

The terms used herein are merely for the purpose of describing specific examples and are not intended to limit the example examples. Unless the context clearly indicates otherwise, the singular forms “a” and “an” used herein are also intended to include the plural forms. It should also be understood that the terms “comprise comprise” and/or “comprise” used herein specify the presence of the stated features, integers, steps, operations, units and/or components, but do not exclude the presence or addition of one or more other features, integers, steps, operations, units, components and/or combinations thereof.

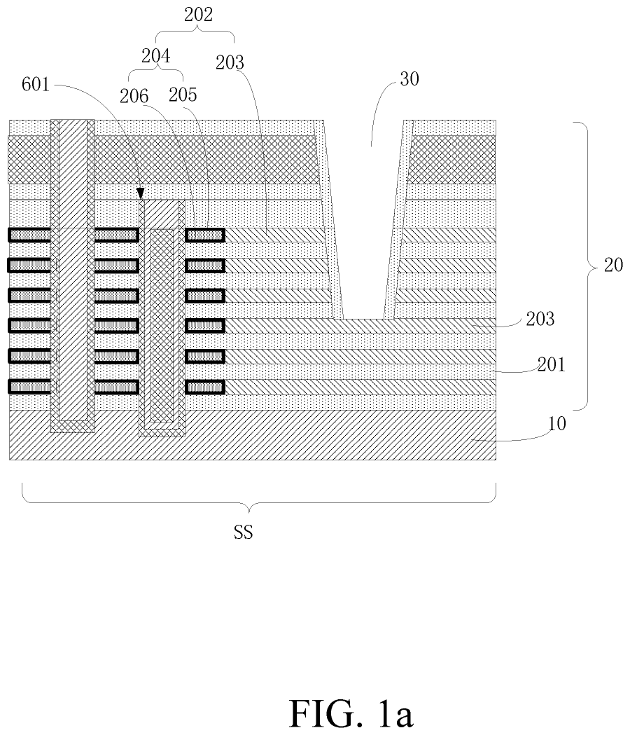

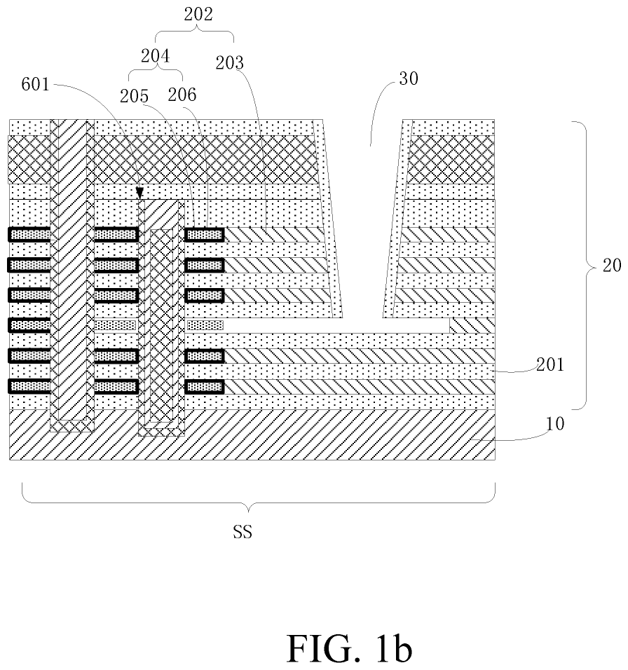

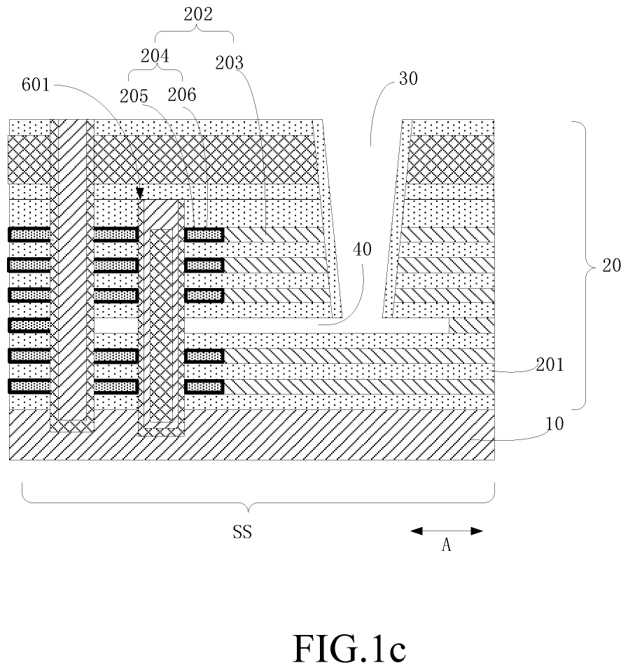

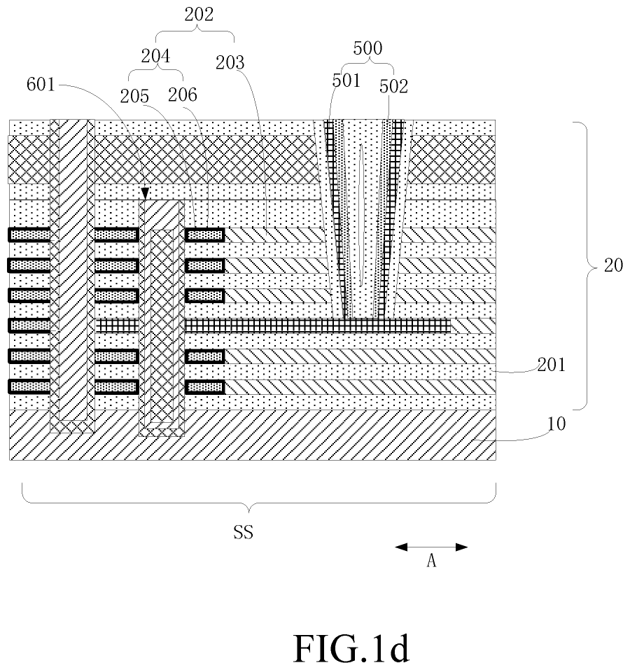

In some examples, when forming a contact structure in a semiconductor device, a substrate 10 and a stack structure 20 on the substrate 10 are provided, as shown in FIG. 1a. The stack structure 20 includes interlayer insulating layers 201 and interlayer material layers 202 which are alternately stacked, and the interlayer material layer 202 comprises an interlayer sacrificial layer 203 and a gate structure 204. A first contact hole 30 is formed in a connection region SS, and the first contact hole 30 extends from a side of the stack structure 20 facing away from the substrate 10 to an interlayer sacrificial layer 203.

As shown in FIG. 1b, the interlayer sacrificial layer 203 is etched through the first contact hole 30 to expose the gate structure 204. Since the gate structure 204 comprises a gate layer 205 and a high-dielectric-constant dielectric layer 206 on outside surfaces of the gate layer 205, and a material used to etch the interlayer sacrificial layer 203 will also etch the high-dielectric-constant dielectric layer 206 at a higher etching rate, when the interlayer sacrificial layer 203 is etched through the first contact hole 30, it is easy for the high-dielectric-constant dielectric layer 206 to be heavily etched so that part of the gate layer 205 is suspended, as shown in FIG. 1b.

In order to prevent the suspended part of the gate layer 205 from falling and damaging the interlayer insulating layer 201, part of the gate layer 205 is removed to form a second contact hole 40 communicated with the first contact hole 30, as shown in FIG. 1c. Since part of the gate structure 204 is etched, the second contact hole 40 has a larger size in a first direction A.

Then, as shown in FIG. 1d, a contact structure 500 is formed in the first contact hole 30 and the second contact hole 40, and the contact structure 500 is connected with the remaining gate structure 204. Specifically, an adhesive layer 501 is first formed on sidewall of the first contact hole 30 and in the second contact hole 40 and is connected with the remaining gate structure 204, and then a conductive layer 502 is formed in the first contact hole 30.

Since the second contact hole 40 has a larger size in the first direction A, the adhesive layer 501 has a relatively poor filling effect in the second contact hole 40, affecting the reliability of the semiconductor device. Moreover, since there is no high-dielectric-constant dielectric layer around the adhesive layer 501 in the second contact hole 40 (i.e., the adhesive layer 501 between two adjacent interlayer insulating layers 201), there is a risk of electric leakage between word lines (a film layer between two adjacent interlayer insulating layers 201 may form a word line). In addition, when the connection region SS has a dummy channel structure 601, the high-dielectric-constant dielectric layer 206 on sidewall of the dummy channel structure 601 is easily removed when the interlayer sacrificial layer 203 is etched through the first contact hole 30. After the adhesive layer 501 is formed, there is no high-dielectric-constant dielectric layer between the adhesive layer 501 and the dummy channel structure 601 so that there is a risk of electric leakage between the dummy channel structure 601 and the word line.

In view of the above, an example of the present disclosure provides a manufacturing method of a semiconductor device.

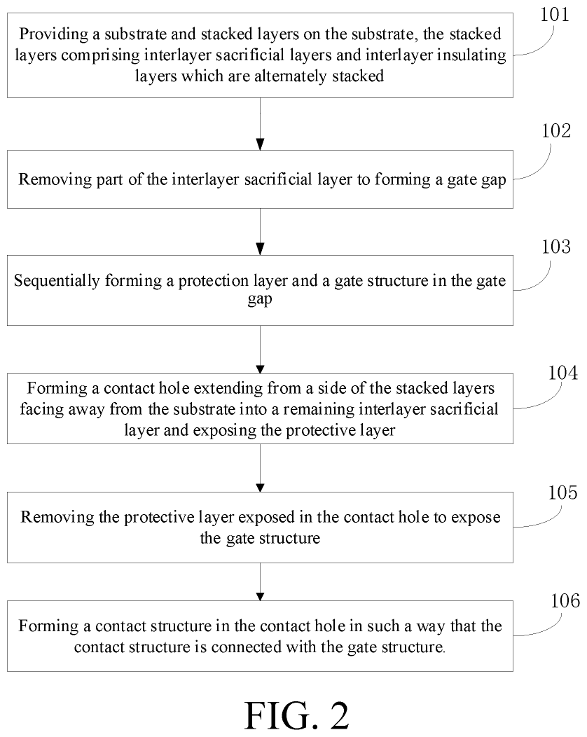

As shown in FIG. 2, the manufacturing method of the semiconductor device provided by the example of the present disclosure includes steps 101 to 106, specifically as follows:

Step 101: a substrate and stacked layers on the substrate are provided, the stacked layers comprise interlayer sacrificial layers and interlayer insulating layers which are alternately stacked.

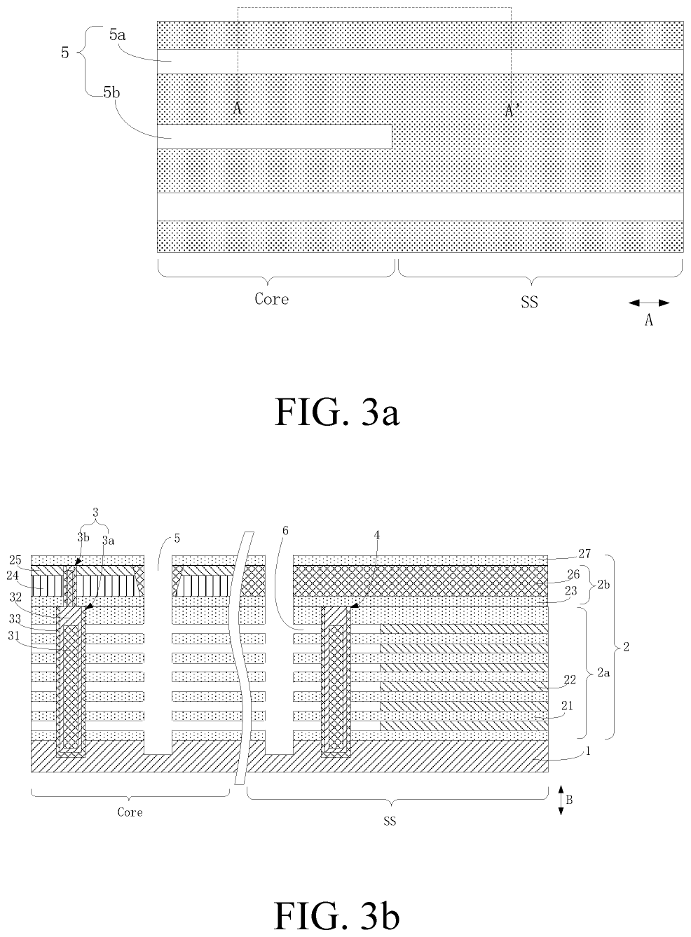

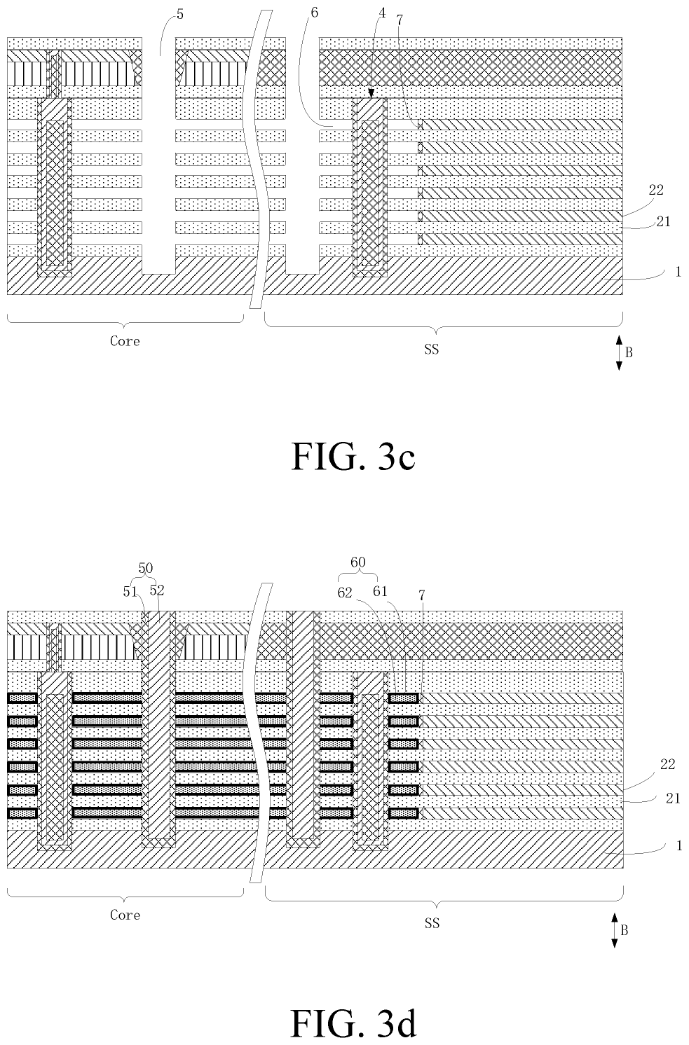

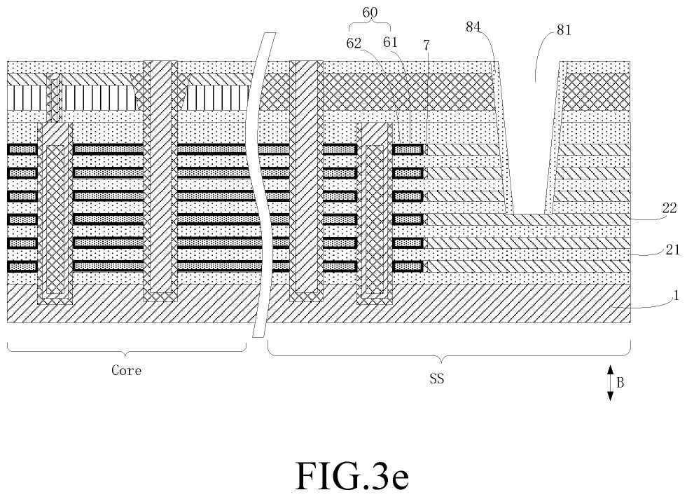

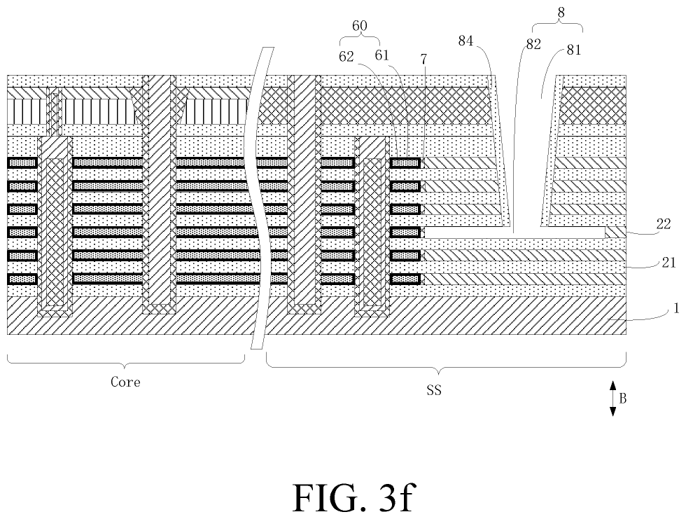

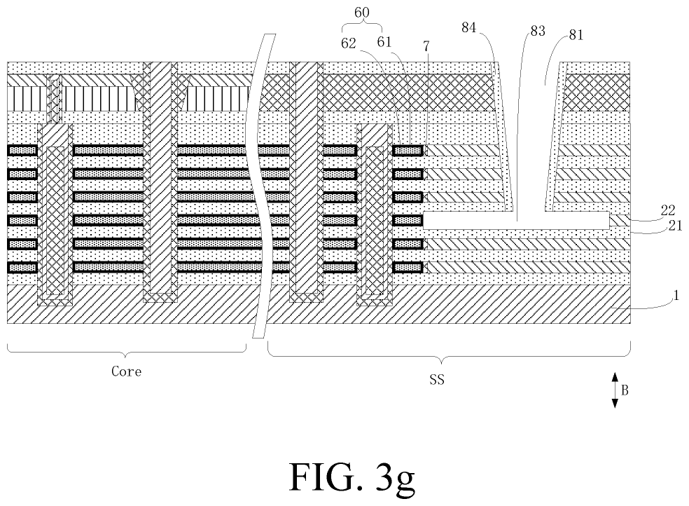

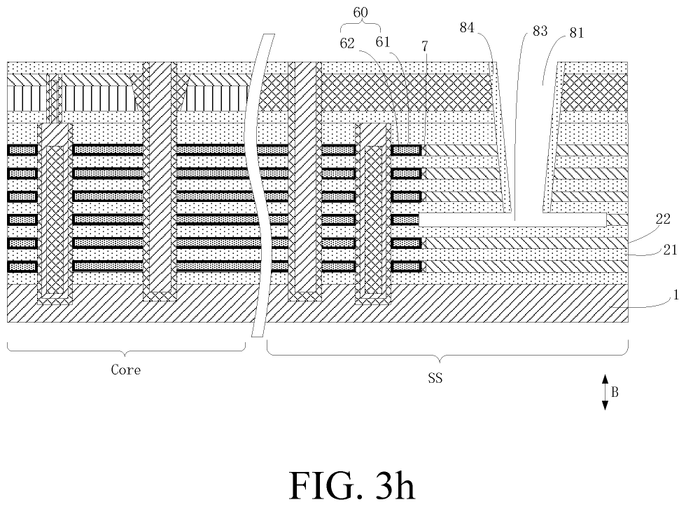

In conjunction with FIG. 3a and FIG. 3b, FIG. 3b is a schematic cross-sectional view taken along a dotted line AA′ in FIG. 3a. The substrate 1 may comprise a core region and a connection region SS distributed along the first direction A. Specifically, the connection region SS can be positioned between two adjacent core regions, or on opposite sides of a core region, which is not specifically limited herein. The substrate 1 may be a base, for example, the material of the substrate 1 may include monocrystalline silicon, polycrystalline silicon, monocrystalline germanium. III-V compound semiconductor materials, II-VI compound semiconductor materials or other semiconductor materials. The substrate 1 may also be a multilayer composite structure. For example, the substrate 1 may include silicon oxide layers and polycrystalline silicon layers which are alternately stacked. In addition, the substrate 1 can be removed in subsequent manufacturing processes so that there is no substrate 1 in the resulting semiconductor device.

The stacked layers 2 are positioned in the core region and the connection region SS, and are positioned on one side of the substrate 1. The stacked layers 2 comprise interlayer insulating layers 21 and interlayer sacrificial layers 22 which are alternately stacked in a second direction B. The number of layers stacked in the stacked layers 2 may be 32, 64, 128 and the like, which is not specifically limited herein. The material of the interlayer insulating layer 21 may include at least one of silicon oxide, silicon nitride, silicon oxynitride, doped silicon oxide, and organosilicate glass and the like, the material of the interlayer sacrificial layer 22 may include at least one of silicon nitride, polycrystalline silicon, and polycrystalline germanium. The material of the interlayer insulating layer 21 is different from that of the interlayer sacrificial layer 22, for example, the material of the interlayer insulating layer 21 is silicon oxide, the material of the interlayer sacrificial layer 22 is silicon nitride.

In some examples, the stacked layers 2 may also comprise other film layers. As shown in FIG. 3b, the stacked layers 2 comprise a plurality of stacked sub-layers, such as first stacked sub-layers 2a and second stacked sub-layers 2b on a side of the first stacked sub-layers 2a facing away from the substrate 1. The first stacked sub-layers 2a comprise interlayer insulating layers 21 and interlayer sacrificial layers 22 which are alternately stacked along the second direction B. The second stacked sub-layers 2b comprise a first insulating layer 23, a select gate line layer 24, a second insulating layer 25 and a third insulating layer 26. The first insulating layer 23 is positioned in the core region Core and the connection region SS, and is positioned on the side of the first stacked sub-layers 2a facing away from the substrate 1. The select gate line layer 24 is positioned in the core region Core, and positioned on a side of the first insulating layer 23 facing away from the substrate 1. The second insulating layer 25 is positioned in the core region Core, and positioned on a side of the select gate line layer facing away from the substrate 1. The third insulating layer 26 is positioned in the connection region SS, and positioned on the side of the first insulating layer 23 facing away from the substrate 1. The materials of the first insulating layer 23, the second insulating layer 25 and the third insulating layer 26 may all include at least one of silicon oxide, silicon nitride, silicon oxynitride, doped silicon oxide, organosilicate glass and the like, the material of the select gate line layer 24 may include at least one of tungsten, cobalt, copper, aluminum, doped polycrystalline silicon, metal silicide and the like.

The stacked layers 2 in the core region Core also have a memory channel structure 3, which penetrates through the stacked layers 2 and extends into the substrate 1 along the second direction B from the side of the stacked layers 2 facing away from the substrate 1. The memory channel structure 3 may comprise a channel filling layer 31, a channel layer 32 disposed around the channel filling layer 31, and a storage medium layer 33 disposed around the channel layer 32. The storage medium layer 33 may include a tunnel layer (not shown) disposed around the channel layer 32, a charge storage layer (not shown) disposed around the tunnel layer, and a charge barrier layer (not shown) disposed around the charge storage layer. The channel filling layer 31 may be an oxide such as silicon oxide, silicon nitride and silicon oxynitride and the like, the channel layer 32 may be a semiconductor layer such as polycrystalline silicon and the like, the tunnel layer may be an oxide such as silicon oxide, silicon nitride, silicon oxynitride and the like, the charge storage layer may be an insulating layer comprising quantum dots or nanocrystals or compounds containing nitrogen and silicon, the charge barrier layer may be an oxide such as silicon oxide and the like.

In some examples, the memory channel structure 3 may include a plurality of memory channel sub-structures disposed in one-to-one correspondence with the plurality of stacked sub-layers. As shown in FIG. 3b, the memory channel structure 3 may include a first memory channel sub-structure 3a and a second memory channel sub-structure 3b. The first memory channel sub-structure 3a penetrates through the first stacked sub-layer 2a and extends into the substrate 1 along the second direction B, the second memory channel sub-structure 3b penetrates through the second stacked sub-layer 2b along the second direction B, and is connected with the first memory channel sub-structure 3a. The first memory channel sub-structure 3a and the second memory channel sub-structure 3b each comprise a channel filling layer 31, a channel layer 32 and a storage medium layer 33. The channel layer 32 in the second memory channel sub-structure 3b is connected with the channel layer 32 in the first memory channel sub-structure 3a, so that the second memory channel sub-structure 3b is electrically connected with the first memory channel sub-structure 3a.

There is also a dummy channel structure 4 in the stacked layers 2 in the connection region SS. The dummy channel structure 4 penetrates through the first stacked sub-layer 2a and extends into the substrate 1 along the second direction B, the second stacked sub-layers 2b cover the dummy channel structure 4. The dummy channel structure 4 may have the same structure as the first memory channel sub-structure 3a, which will not be described in detail herein.

In some examples, the stacked layers 2 further comprise a fourth insulating layer 27. The fourth insulating layer 27 is positioned in the core region Core and the connection region SS, and is positioned on a side of the second stacked sub-layers 2b facing away from the substrate 1, and the fourth insulating layer 27 covers the memory channel structure 3. The material of the fourth insulating layer 27 may include at least one of silicon oxide, silicon nitride, silicon oxynitride, doped silicon oxide, organosilicate glass and the like.

Step 102: parts of the interlayer sacrificial layers are removed to form gate gaps.

In the example of the present disclosure, a gate line slit may be formed first to remove parts of the interlayer sacrificial layers through the gate line slit. As shown in FIG. 3a, the gate line slit 5 extends in the first direction A and is positioned in the core region Core and the connection region SS. In some examples, the gate line slit 5 may comprise a plurality of slits. As shown in FIG. 3a, the gate line slit 5 may comprise a first slit 5a and a second slit 5b. The first slit Sa is positioned in the core region Core and the connection region SS, the second slit Sb is positioned in the core region Core, and there is a second slit 5b between two adjacent first slits 5a. As shown in FIG. 3b, in the second direction B, the gate line slit 5 penetrates through the stacked layers 2 from the side of the stacked layers 2 facing away from the substrate 1 and extend into the substrate 1.

The interlayer sacrificial layers 22 in the stacked layers 2 are etched through the gate line slit 5 to remove parts of the interlayer sacrificial layers 22. The removed parts of the interlayer sacrificial layers 22 comprise the interlayer sacrificial layer 22 in the core region Core and parts of the interlayer sacrificial layers 22 in the connection region SS, thereby forming the gate gaps 6 between the interlayer insulating layers 21. The gate gaps 6 are positioned in the core region Core and part of the connection region SS, and are communicated with the gate line slit 5. The remaining interlayer sacrificial layers 22 after parts of the interlayer sacrificial layer 22 are removed are positioned in the connection region SS.

In some examples, the interlayer sacrificial layers 22 in the core region Core and the interlayer sacrificial layers 22 in the connection region SS may be removed separately. For example, a sacrificial layer (not shown) is first filled in the gate line slit 5 in the connection region SS, and then the interlayer sacrificial layers 22 in the core region Core are etched through the gate line slit 5 in the core region Core to completely remove the interlayer sacrificial layers 22 in the core region Core. Then, the sacrificial layer filled in the gate line slit 5 in the connection region SS is removed, and a sacrificial layer (not shown) is filled in the gate line slit 5 in the core region Core. Then, the interlayer sacrificial layers 22 in the connection region SS are etched through the gate line slit 5 in the connection region SS to remove parts of the interlayer sacrificial layers 22 in the connection region SS. Then, the sacrificial layer in the gate line slit 5 in the core region Core is removed.

Step 103: a protection layer and a gate structures are sequentially formed in the gate gap.

Since the gate line slit 5 is communicated with the gate gap 6, the protection layer 7 and the gate structure 60 can be sequentially formed in the gate gap 6 through the gate line slit 5.

Specifically, sequentially forming the protection layer and the gate structure in the gate gap in step 103 comprises:

forming the protection layer at the remaining interlayer sacrificial layer exposed in the gate gap;

filling the gate structure in the gate gap.

Since the gate gap 6 is formed by removing part of the interlayer sacrificial layer 22, the gate gap 6 exposes the remaining interlayer sacrificial layer 22. As shown in FIG. 3c, the protection layer 7 is formed in the gate gap 6 through the gate line slit 5. It should be noted that the protection layer 7 is positioned in the connection region SS, and positioned at the remaining interlayer sacrificial layer 22 exposed in the gate gap 6.

In order to prevent the protection layer 7 from being formed at other positions in the gate gap 6 like the surface of the interlayer insulating layer 21, which will result in increase of the thickness of the interlayer insulating layer 21, an oxidation process is adopted to form the protection layer 7 in this example.

Specifically, the step of forming the protection layer at the remaining interlayer sacrificial layer exposed in the gate gap comprises:

oxidizing the remaining interlayer sacrificial layer exposed in the gate gap to form the protection layer.

After the remaining interlayer sacrificial layer 22 is exposed in the gate gap 6, the remaining interlayer sacrificial layer 22 exposed in the gate gap 6 is oxidized by using an oxidation process to form the protection layer 7 on a surface of the remaining interlayer sacrificial layer 22 exposed in the gate gap 6. The material of the protection layer 7 may be oxide, for example, the material of the interlayer sacrificial layer 22 is silicon nitride, the material of the protection layer 7 is silicon oxide.

After the protection layer 7 is formed, as shown in FIG. 3d, a gate structure 60 may be formed in the gate gap 6 by using a thin film deposition process. The thin film deposition process may be physical vapor deposition, chemical vapor deposition, atomic layer deposition, laser-assisted deposition and the like. The gate structure 60 is positioned in the core region Core and the connection region SS, and is disposed in the same layer as the remaining interlayer sacrificial layer 22. The gate structure 60 may comprise a high-dielectric-constant dielectric layer 61 and a gate layer 62. The high-dielectric-constant dielectric layer 61 is positioned between the gate layer 62 and the interlayer insulating layer 21 and between the gate layer 62 and the protection layer 7. Specifically, the high-dielectric-constant dielectric layer 61 is first deposited on surfaces of the exposed interlayer insulating layer 21 and the protection layer 7 in the gate gap 6, and then the gate layer 62 is filled in the gate gap 6.

In addition, since the memory channel structure 3 and the dummy channel structure 4 are formed in the stacked layers 2 in advance, the gate gap 6 also exposes partial sidewall of the memory channel structure 3 and the dummy channel structure 4 when part of the interlayer sacrificial layer 22 is removed to form the gate gap 6. When the high-dielectric-constant dielectric layer 61 is deposited in the gate gap 6, the high-dielectric-constant dielectric layer 61 is also deposited at sidewall of the exposed memory channel structure 3 and the dummy channel structure 4 in the gate gap 6.

The high-dielectric-constant dielectric layer 61 has a larger dielectric constant value, which may be greater than or equal to 7. The material of the high-dielectric-constant dielectric layer 61 may be aluminum oxide, hafnium oxide, tantalum oxide and the like, the material of the gate layer 62 may include at least one of tungsten, cobalt, copper, aluminum, doped polycrystalline silicon, metal silicide and the like.

After the gate structure 60 is formed in the gate gap 6, as shown in FIG. 3d, a gate line slit structure 50 is formed in the gate line slit 5 by using a thin film deposition process. The gate line slit structure 50 may comprise a blocking layer 51 and a conductive layer 52. The conductive layer 52 extends into the substrate 1 from the side of the stacked layers 2 facing away from the substrate 1, the blocking layer 51 is disposed around the conductive layer 52. The material of the blocking layer 51 may include at least one of silicon oxide, silicon nitride, silicon oxynitride, doped silicon oxide, organosilicate glass and the like. The material of the conductive layer 52 may include polycrystalline silicon and the like.

Step 104: a contact hole which extends from the side of the stacked layers facing away from the substrate into a remaining interlayer sacrificial layer is formed, and the protection layer is exposed.

The contact hole is positioned in the connection region SS. There may be a plurality of contact holes, the stacked layers 2 comprise a plurality of remaining interlayer sacrificial layers 22, the plurality of contact holes are disposed in one-to-one correspondence with plurality of the remaining interlayer sacrificial layers 22. In the second direction B, each of the contact holes extends from the side of the stacked layers 2 facing away from the substrate 1 into a corresponding remaining interlayer sacrificial layer 22 to expose the protection layer 7 corresponding to the remaining interlayer sacrificial layer 22.

The contact hole comprises a first contact sub-hole and a second contact sub-hole communicated with each other, that is, the contact hole may be formed by using two etching processes. Specifically, forming the contact hole in the step 104 comprises:

forming the first contact sub-hole which extends from the side of the stacked layers facing away from the substrate to the remaining interlayer sacrificial layer;

removing at least part of the remaining interlayer sacrificial layer to form the second contact sub-hole to expose the protection layer.

As shown in FIG. 3e, the stacked layers 2 are etched by using an etching process to form a first contact sub-hole 81 which extends from the side of the stacked layers 2 facing away from the substrate 1 to a remaining interlayer sacrificial layer 22 along the second direction B. Specifically, a bottom of the first contact sub-hole 81 (i.e., an end of the first contact sub-hole 81 close to the substrate) may be positioned on a surface of the remaining interlayer sacrificial layer 22 facing away from the substrate.

Then, the remaining interlayer sacrificial layer 22 may be etched through the first contact sub-hole 81 to form the second contact sub-hole 82. In order to avoid etching other remaining interlayer sacrificial layers 22 exposed in the first contact sub-hole 81 when etching the remaining interlayer sacrificial layer 22, it is also necessary to form an isolation layer on sidewall of the first contact sub-hole 81. Specifically, prior to the step of removing at least part of the remaining interlayer sacrificial layer, the method further includes: forming an isolation layer on sidewall of the first contact sub-hole.

As shown in FIG. 3e, an isolation layer 84 is formed on the sidewall of the first contact sub-hole 81 to prevent other remaining interlayer sacrificial layers 22 from being exposed in the first contact sub-hole 81. The material of the isolation layer 84 may include at least one of silicon oxide, silicon nitride, silicon oxynitride, doped silicon oxide, organosilicate glass and the like. The material of the isolation layer 84 is different from that of the remaining interlayer sacrificial layer 22. For example, the material of the remaining interlayer sacrificial layer 22 is silicon nitride, the material of the isolation layer 84 is silicon oxide.

Then, as shown in FIG. 3f, the remaining interlayer sacrificial layer 22 at the bottom of the first contact sub-hole 81 is etched through the first contact sub-hole 81 by using an etching process to remove at least part of the remaining interlayer sacrificial layer 22 to form the second contact sub-hole 82. Specifically, at least the remaining interlayer sacrificial layer 22 between the first contact hole 81 and the protection layer 7 is removed, such that the second contact hole 82 is positioned at least between the first contact hole 81 and the protection layer 7, the second contact hole 82 exposes the protection layer 7. The first contact hole 81 and the second contact hole 82 communicated with each other constitute the contact hole 8.

It should be noted that, due to the provision of the protection layer 7, the high-dielectric-constant dielectric layer 61 in the gate structure 60 will not be etched when the remaining interlayer sacrificial layer 22 is etched to form the second contact sub-hole 82, thus avoiding the loss of the gate structure 60.

Step 105: the protection layer exposed in the contact hole is removed to expose the gate structure.

Since it is necessary to subsequently form a contact structure connected with the gate structure 60 in the contact hole 8, the protection layer 7 exposed in the contact hole 8 needs to be etched so that the contact hole 8 exposes the gate structure 60.

Specifically, removing the protection layer exposed in the contact hole to expose the gate structure in the step 105 comprises:

removing the protection layer exposed in the contact hole to expose the high-dielectric-constant dielectric layer;

removing the high-dielectric-constant dielectric layer exposed in the contact hole to expose the gate layer.

The protection layer 7 is etched through the second contact hole 82 by using an etching process to remove the protection layer 7 exposed by the second contact hole 82. In some examples, the material of the interlayer insulating layer 21 is same as the material of the protection layer 7. Since the second contact sub-hole 82 also exposes part of the interlayer insulating layer 21, the exposed interlayer insulating layer 21 will also be etched while the exposed protection layer 7 is etched through the second contact sub-hole 82.

Specifically, the method further comprises:

etching the interlayer insulating layer exposed in the second contact sub-hole to form a third contact sub-hole when the protection layer exposed in the contact hole is removed, the third contact sub-hole having a larger size than that of the second contact sub-hole along the stacking direction of the stacked layers.

As shown in FIG. 3g, when the protection layer 7 exposed by the second contact sub-hole 82 is removed, the interlayer insulating layer 21 exposed by the second contact sub-hole 82 is also etched to expand the second contact sub-hole 82 into the third contact sub-hole 83. The third contact hole 83 encompasses the second contact hole 82, and has a larger size than that of the second contact hole 82 along the stacking direction (i.e., the second direction B) of the stacked layers 2. That is, the interlayer insulating layer 21 exposed in the second contact sub-hole 82 becomes thinner. The material of the interlayer insulating layer 21 is same as the material of the protection layer 7. For example, both the interlayer insulating layer 21 and the protection layer 7 are silicon oxide.

Since the gate structure 60 includes the high-dielectric-constant dielectric layer 61 and the gate layer 62, and there is the high-dielectric-constant dielectric layer 61 between the gate layer 62 and the protection layer 7, the high-dielectric-constant dielectric layer 61 is exposed after the protection layer 7 exposed in the contact hole 8 is removed. Since the contact structure formed subsequently in the contact hole 8 needs to be connected with the gate layer 62, the exposed high-dielectric-constant dielectric layer 61 also needs to be etched to expose the gate layer 62 after the contact hole 8 exposes the high-dielectric-constant dielectric layer 61.

As shown in FIG. 3h, the high-dielectric-constant dielectric layer 61 exposed in the contact hole 8 is etched by using an etching process to remove part of the high-dielectric-constant dielectric layer 61. It should be noted that the etching process may be performed at a lower etching rate to ensure that only the high-dielectric-constant dielectric layer 61 exposed in the contact hole 8 is etched without etching the high-dielectric-constant dielectric layer 61 between the gate layer 62 and the interlayer insulating layer 21, so that the gate layer 62 will not be etched. Thus, the high-dielectric-constant dielectric layer 61 between the gate layers 62 is retained, which reduces the risk of electric leakage between word lines (a film layer between two adjacent interlayer insulating layers 21 may constitute a word line). In addition, the high-dielectric-constant dielectric layer 61 on sidewall of the dummy channel structure 4 is also retained, which reduces the risk of electric leakage between the dummy channel structure 4 and the word line.

After removing the high-dielectric-constant dielectric layer 61 exposed in the contact hole 8, the contact hole 8 exposes the gate layer 62.

Step 106: a contact structure is formed in the contact hole in such a way that the contact structure is connected with the gate structure.

As shown in FIG. 3i, after the contact hole 8 exposes the gate structure 60, a contact structure 9 may be formed in the contact hole 8 in such a way that the contact structure 9 is connected with the gate structure 60. Specifically, the contact structure 9 is connected with the gate layer 62 in the gate structure 60. The contact structure 9 may comprise an adhesive layer 91 and a conductive layer 92.

Specifically, forming the contact structure in the contact hole in the step 106 comprises:

forming the adhesive layer in the contact hole in such a way that the adhesive layer is positioned on the sidewall of the first contact sub-hole and filled in the second contact sub-hole to be connected with the gate layer;

forming the conductive layer surrounded by the adhesive layer in the first contact sub-hole.

The adhesive layer 91 is first formed in the contact hole 8 by using a thin film deposition process. The adhesive layer 91 is positioned on the sidewall of the first contact sub-hole 81 and filled in the second contact sub-hole 82 to be connected with the gate layer 62 in the gate structure 60. In some examples, as shown in FIG. 3i, the second contact hole 82 is expanded into the third contact hole 83, and thus the adhesive layer 91 is positioned on the sidewall of the first contact hole 81 and filled in the third contact hole 83 to be connected with the gate layer 62 in the gate structure 60. The material of the adhesive layer 91 may include conductive materials such as titanium nitride, tantalum nitride and tungsten carbide and the like.

It should be noted that the gate structure 60 is not heavily etched in the example of the present disclosure, so that the second contact hole 82/the third contact hole 83 has a smaller size in the first direction A, which improves the filling effect of the adhesive layer 91 in the second contact hole 82/the third contact hole 83, thereby improving the reliability of the semiconductor device. In addition, the adhesive layer 91 filled in the third contact sub-hole 83 becomes thicker, that is, the adhesive layer 91 has a greater thickness than that of the gate structure 60, which can reduce the resistance of the adhesive layer 91 and improve the electrical performance of the semiconductor device.

Then, the conductive layer 92 is formed on the surface of the adhesive layer 91 in the first contact sub-hole 81 by using a thin film deposition process in such a way that the conductive layer 92 is surrounded by the adhesive layer 91. The provision of the adhesive layer 91 can improve the adhesive force of the conductive layer 92, and prevent the conductive layer 92 from contacting with the interlayer insulating layer 21 so as to damage the interlayer insulating layer 21. The material of the conductive layer 92 includes at least one of tungsten, cobalt, copper, aluminum, doped polycrystalline silicon, metal silicide and the like.

It should be noted that if the conductive layer 92 is in direct contact with the interlayer insulating layer 21, the interlayer insulating layer may be damaged. Therefore, the adhesive layer 91 is filled in the second contact sub-hole 82/third contact sub-hole 83 to isolate the conductive layer 92 from the interlayer insulating layer 21.

The contact structure 9 may further comprise a filling layer 93. After the conductive layer 92 is formed, the filling layer 93 is formed in the second contact sub-hole 82. The material of the filling layer 93 may include at least one of silicon oxide, silicon nitride, silicon oxynitride, doped silicon oxide, organosilicate glass and the like.

According to the manufacturing method of the semiconductor device provided by the examples of the present disclosure, after part of an interlayer sacrificial layer is removed to form a gate gap, a protection layer and a gate structure can be sequentially formed in the gate gap, so that the protection layer is removed to form a contact structure connected with the gate structure in the contact hole after a contact hole is formed. Due to provision of the protection layer, the gate structure can be prevented from being etched when the contact hole is formed, so that the loss of the gate structure is avoided, the risk of electric leakage is reduced.

Correspondingly, an example of the present disclosure further provides a semiconductor device which can be formed by adopting the above manufacturing method of the semiconductor device. In some examples, the semiconductor device is a memory or a memory array.

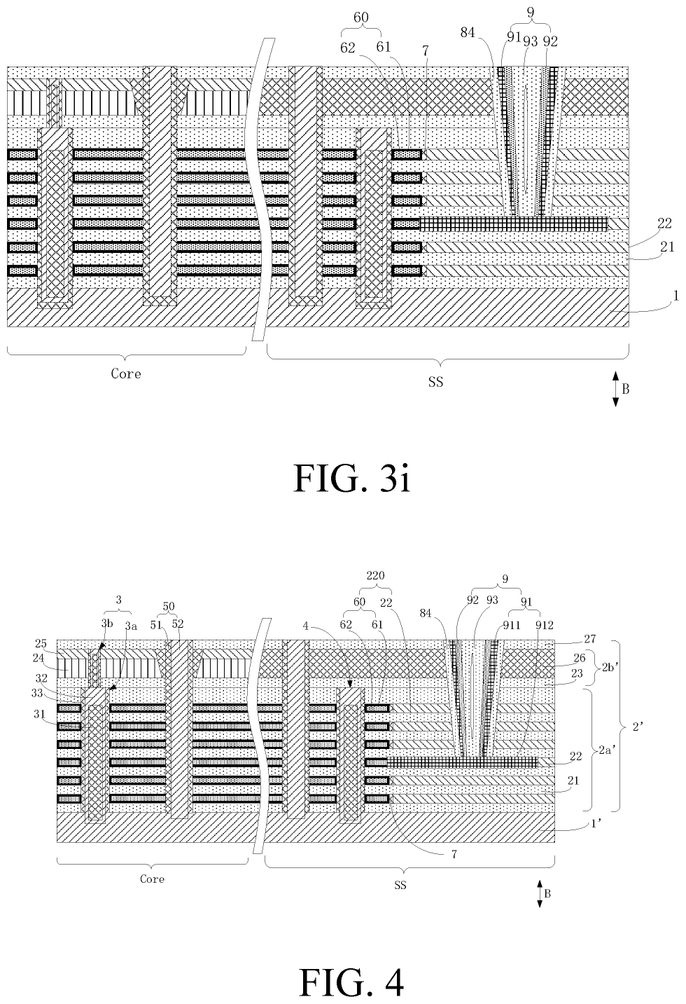

As shown in FIG. 4, the semiconductor device provided by this example comprises a semiconductor layer 1′, a stack structure 2′, a protection layer 7 and a contact structure 9.

The semiconductor layer 1′ may comprise a core region and a connection region SS. The material of the semiconductor layer 1′ may include semiconductor materials such as polycrystalline silicon and the like.

The stack structure 2′ is positioned in the core region Core and the connection region SS, and is positioned on the semiconductor layer 1′. The stack structure 2′ comprises interlayer insulating layers 21 and interlayer material layers 220 which are alternately stacked along a second direction B. The number of layers stacked in the stack structure 2′ may be 32, 64, 128 and the like, which is not specifically limited here. The interlayer material layer 220 comprises a gate structure 60 and an interlayer sacrificial layer 22. The gate structure 60 is positioned in the core region Core and the connection region SS, the interlayer sacrificial layer 22 is positioned in the connection region SS, and the gate structure 60 is disposed in the same layer as the interlayer sacrificial layer 22.

The gate structure 60 may comprise a high-dielectric-constant dielectric layer 61 and a gate layer 62. The high-dielectric-constant dielectric layer 61 is positioned between the gate layer 62 and the interlayer insulating layer 21 and between the gate layer 62 and the interlayer sacrificial layer 22. The high-dielectric-constant dielectric layer 61 has a large dielectric constant value, which may be greater than or equal to 7. The material of the high-dielectric-constant dielectric layer 61 may be aluminum oxide, hafnium oxide, tantalum oxide and the like, and the material of the gate layer 62 may include at least one of tungsten, cobalt, copper, aluminum, doped polycrystalline silicon, metal silicide and the like.

In the example of the present disclosure, the gate structure 60 is not damaged, that is, there is a high-dielectric-constant dielectric layer 61 between the gate layers 62, which reduces the risk of electric leakage between word lines (a film layer between two adjacent interlayer insulating layers 21 may constitute a word line). In addition, sidewall of a dummy channel structure 4 has a high-dielectric-constant dielectric layer 61, which reduces the risk of electric leakage between the dummy channel structure 4 and the word lines.

The material of the interlayer insulating layer 21 may include at least one of silicon oxide, silicon nitride, silicon oxynitride, doped silicon oxide, organosilicate glass and the like. The material of the interlayer sacrificial layer 22 may include at least one of silicon nitride, polycrystalline silicon and polycrystalline germanium. The material of the interlayer insulating layer 21 is different from that of the interlayer sacrificial layer 22, for example, the material of the interlayer insulating layer 21 is silicon oxide, the material of the interlayer sacrificial layer 22 is silicon nitride.

In some examples, the stack structure 2′ may further comprise other film layers. As shown in FIG. 4, the stack structure 2′ comprises a plurality of stacked sub-structures, such as a first stack sub-structure 2a′ and a second stack sub-structure 2b′ on a side of the first stack sub-structure 2a′ facing away from the semiconductor layer 1′. The first stack sub-structure 2′ comprises interlayer insulating layers 21 and interlayer material layers 220 which are alternately stacked along a second direction B. The second stack sub-structure 2b′ comprises a first insulating layer 23, a select gate line layer 24, a second insulating layer 25 and a third insulating layer 26. The first insulating layer 23 is positioned in the core region Core and the connection region SS, and is positioned on the side of the first stack sub-structure 2a′ facing away from the semiconductor layer 1′. The select gate line layer 24 is positioned in the core region Core, and is positioned on a side of the first insulating layer 23 facing away from the semiconductor layer 1′. The second insulating layer 25 is positioned in the core region Core. and is positioned on a side of the select gate line layer facing away from the semiconductor layer 1′. The third insulating layer 26 is positioned in the connection region SS, and is positioned on the side of the first insulating layer 23 facing away from the semiconductor layer 1′. Each of the materials of the first insulating layer 23, the second insulating layer 25 and the third insulating layer 26 may include at least one of silicon oxide, silicon nitride, silicon oxynitride, doped silicon oxide, organosilicate glass and the like, the material of the select gate line layer 24 may include at least one of tungsten, cobalt, copper, aluminum, doped polycrystalline silicon, metal silicide and the like.

The semiconductor device may further comprise a memory channel structure 3 in the core region Core, the memory channel structure 3 penetrates through the stack structure 2′ and extends into the semiconductor layer 1′ along the second direction B from a side of the stack structure 2′ facing away from the semiconductor layer 1′. The memory channel structure 3 may comprise a channel filling layer 31, a channel layer 32 disposed around the channel filling layer 31, and a storage medium layer 33 disposed around the channel layer 32. The channel layer 32 is connected with the semiconductor layer 1′. The storage medium layer 33 may comprise a tunnel layer (not shown) disposed around the channel layer 32, a charge storage layer (not shown) disposed around the tunnel layer, and a charge barrier layer (not shown) disposed around the charge storage layer. The channel filling layer 31 may be an oxide such as silicon oxide, silicon nitride and silicon oxynitride and the like, the channel layer 32 may be a semiconductor layer such as polycrystalline silicon and the like, the tunnel layer may be an oxide such as silicon oxide, silicon nitride, silicon oxynitride and the like, the charge storage layer may be an insulating layer comprising quantum dots or nanocrystals or compounds containing nitrogen and silicon, the charge barrier layer may be an oxide such as silicon oxide and the like.

In some examples, the memory channel structure 3 may comprise a plurality of memory channel sub-structures disposed in one-to-one correspondence with the plurality of stack sub-structures. As shown in FIG. 3b, the memory channel structure 3 may comprise a first memory channel sub-structure 3a and a second memory channel sub-structure 3b. The first memory channel sub-structure 3a penetrates through the first stack sub-structure 2a′ and extends into the semiconductor layer 1′ along the second direction B, the second memory channel sub-structure 3b penetrates through the second stack sub-structure 2b′ along the second direction B. and is connected with the first memory channel sub-structure 3a. The first memory channel sub-structure 3a and the second memory channel sub-structure 3b each comprise a channel filling layer 31, a channel layer 32 and a storage medium layer 33. The channel layer 32 in the second memory channel sub-structure 3b is connected with the channel layer 32 in the first memory channel sub-structure 3a, the channel layer 32 in the first memory channel sub-structure 3a is also connected with the semiconductor layer 1′, so that the second memory channel sub-structure 3b, the first memory channel sub-structure 3a and the semiconductor layer 1′ are electrically connected.

The semiconductor device may further comprise a dummy channel structure 4 in the connection region SS. The dummy channel structure 4 penetrates through the first stacked sub-layers 2a and extends into the semiconductor layer 1′ along the second direction B, the second stack sub-structure 2b′ covers the dummy channel structure 4. The dummy channel structure 4 may have the same structure as the first memory channel sub-structure 3a, which will not be described in detail here.

In some examples, the stack structure 2′ further comprises a fourth insulating layer 27. The fourth insulating layer 27 is positioned in the core region Core and the connection region SS, and is positioned on a side of the second stacked sub-layers 2b facing away from the semiconductor layer 1′, and covers the memory channel structure 3. The material of the fourth insulating layer 27 may include at least one of silicon oxide, silicon nitride, silicon oxynitride, doped silicon oxide, organosilicate glass and the like.

The protection layer 7 is positioned in the connection region SS, and is positioned between the gate structure 60 and the interlayer sacrificial layer 22. Specifically, the protection layer 7 is positioned between the high-dielectric-constant dielectric layer 61 in the gate structure 60 and the interlayer sacrificial layer 22, the high-dielectric-constant dielectric layer 61 is positioned between the gate layer 62 and the interlayer insulating layer 21 and between the gate layer 62 and the protection layer 7. The material of the protection layer 7 may be an oxide, and when the material of the interlayer sacrificial layer 22 is silicon nitride, the material of the protection layer 7 may be silicon oxide.

The contact structure 9 is positioned in the connection region SS, and extends from the side of the stack structure 2′ facing away from the semiconductor layer 1′ into an interlayer sacrificial layer 22 along the second direction B. and is connected with the gate structure 60. Specifically, the contact structure 9 is connected with the gate layer 62 in the gate structure 60. There may be a plurality of contact structures 9, the stack structure 2′ comprises a plurality of interlayer sacrificial layers 22 and a plurality of gate structures 60, the plurality of contact structures 9 are disposed in one-to-one correspondence with the plurality of interlayer sacrificial layers 22, and are disposed in one-to-one correspondence with the plurality of gate structures 60. Each of the contact structures 9 extends from the side of the stack structure 2′ facing away from the semiconductor layer 1′ to a corresponding interlayer sacrificial layer 22 along the second direction B, and is connected with the gate layer 62 in a corresponding gate structure 60.

The contact structure 9 may comprise an adhesive layer 91 and a conductive layer 92. The conductive layer 92 extends from the side of the stack structure 2′ facing away from the semiconductor layer 1′ to an interlayer sacrificial layer 22. The adhesive layer 91 is disposed around the conductive layer 92 and is connected with the gate layer 62. The material of the adhesive layer 91 may include conductive materials such as titanium nitride, tantalum nitride and tungsten carbide and the like. The material of the conductive layer 92 includes at least one of tungsten, cobalt, copper, aluminum, doped polycrystalline silicon, metal silicide and the like.

The adhesive layer 91 may comprise a first adhesive sub-layer 911 and a second adhesive sub-layer 912. The first adhesive sub-layer 911 is positioned on the second adhesive sub-layer 912 and is disposed around the conductive layer 92. The second adhesive sub-layer 912 is disposed in the same layer as the gate structure 60, that is, the second adhesive sub-layer 912 is positioned between two adjacent interlayer insulating layers 21, and the second adhesive sub-layer 912 is connected with the gate layer 62 in the gate structure 60.

The second adhesive sub-layer 912 has a greater thickness than that of the gate structure 60. Accordingly, the interlayer insulating layer 21 in contact with the second adhesive sub-layer 912 has a smaller thickness than that of the interlayer insulating layer 21 not in contact with the second adhesive sub-layer 912. In this example, increasing the thickness of the second adhesive sub-layer 912 can reduce the resistance of the second adhesive sub-layer and improve the electrical performance of the semiconductor device.

The contact structure 9 may further comprise a filling layer 93, the conductive layer 92 is disposed around the filling layer 93. The material of the filling layer 93 may include at least one of silicon oxide, silicon nitride, silicon oxynitride, doped silicon oxide, organosilicate glass and the like.

The semiconductor device may further comprise an isolation layer 84 disposed around the first adhesive sub-layer 911. The material of the isolation layer 84 may include at least one of silicon oxide, silicon nitride, silicon oxynitride, doped silicon oxide, organosilicate glass and the like.

The semiconductor device further comprises a gate line slit structure 50 which extends into the semiconductor layer 1′ from the side of the stack structure 2′ facing away from the semiconductor layer 1′. The gate line slit structure 50 includes a blocking layer 51 and a conductive layer 52. The conductive layer 52 is connected with the semiconductor layer 1′, the blocking layer 51 is disposed around the conductive layer 52. The material of the blocking layer 51 may include at least one of silicon oxide, silicon nitride, silicon oxynitride, doped silicon oxide, organosilicate glass and the like. The material of the conductive layer 52 may include polycrystalline silicon and the like.

The example of the present disclosure provides a semiconductor device, in which a protection layer is disposed between the gate structure and the interlayer sacrificial layer to protect the gate structure, thereby avoiding the loss of the gate structure, reducing the risk of electric leakage and improving the reliability of the semiconductor device.

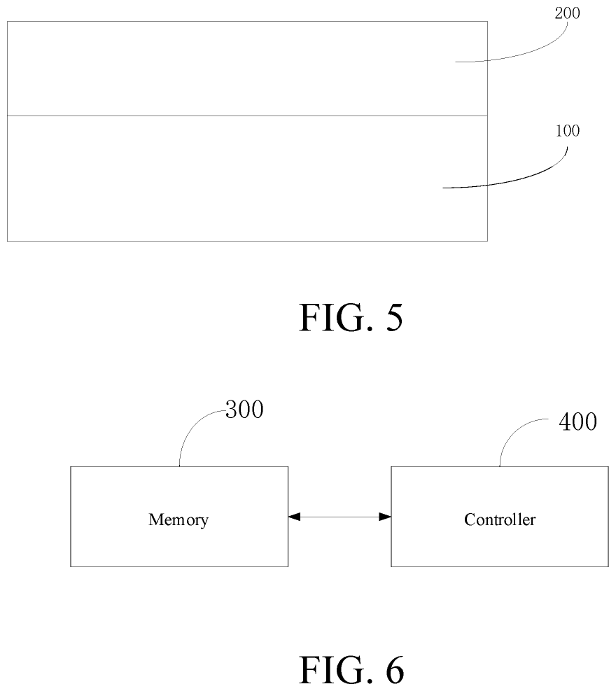

Referring to FIG. 5, it is a schematic structural diagram of a memory provided by an example of the present disclosure.

As shown in FIG. 5, the memory comprises a memory array 100 and a peripheral device 200 connected with the memory array 100. The memory array 100 may comprise the semiconductor device described in the above examples, which will not be described in detail here.

The memory array 100 may be a nonvolatile memory array, for example, a NAND flash memory, a NOR flash memory and the like. The peripheral device 200 may comprise a complementary metal oxide semiconductor (CMOS), a static random access memory (SRAM), a dynamic random access memory (DRAM), a field programmable gate array (FPGA), a central processing unit (CPU), an Xpoint chip and the like.

Specifically, the peripheral device 200 may be positioned on the memory array 100 and bonded with the memory array 100. The memory array 100 and the peripheral devices 200 may also adopt other architectural forms. For example, the peripheral device 200 is positioned below the memory array 100, i.e., a periphery under core array (PUC) architecture, or the peripheral device 200 and the memory array 100 are disposed side by side, i.e., a periphery near core array (PNC) architecture and the like, which is not specifically limited here.

The memory provided by the example of the present disclosure can improve the reliability and electrical performance of the memory.

Referring to FIG. 6, it is a schematic structural diagram of a memory system provided by an example of the present disclosure.

As shown in FIG. 6, an example of the present disclosure further provides a memory system, which comprises a memory 300 and a controller 400. The memory 300 is electrically connected with the controller 400, the controller 400 is conFIGured for controlling the memory 300 to store data. The memory 300 is the memory described in the above examples, and will not be described in detail here. The controller 400 may be a controller well known to those skilled in the art, and will not be described in detail here.

The memory system may be applied to terminal products such as computers, televisions, set-top boxes and vehicles.

The present disclosure provides a semiconductor device and a manufacturing method thereof, a memory and a memory system, which can reduce the risk of electric leakage and improve the reliability of a memory.

The present disclosure provides a manufacturing method of a semiconductor device, which comprises:

providing a substrate and stacked layers on the substrate, the stacked layers comprising interlayer sacrificial layers and interlayer insulating layers which are alternately stacked;

removing part of the interlayer sacrificial layer to form a gate gap;

sequentially forming a protection layer and a gate structure in the gate gap;

forming a contact hole extending from a side of the stacked layers facing away from the substrate into a remaining interlayer sacrificial layer and exposing the protection layer;

removing the protection layer exposed in the contact hole to expose the gate structure; and

forming a contact structure in the contact hole in such a way that the contact structure is connected with the gate structure.

Optionally, the step of sequentially forming the protection layer and the gate structure in the gate gap comprises:

forming the protection layer at the remaining interlayer sacrificial layer exposed in the gate gap;

filling the gate structure in the gate gap.

Optionally, the step of forming the protection layer at the remaining interlayer sacrificial layer exposed in the gate gap comprises:

oxidizing the remaining interlayer sacrificial layer exposed in the gate gap to form the protection layer.

Optionally, the contact hole comprises a first contact sub-hole and a second contact sub-hole communicated with each other;

The step of forming the contact hole comprises:

forming the first contact sub-hole extending from the side of the stacked layers facing away from the substrate to the remaining interlayer sacrificial layer;

removing at least part of the remaining interlayer sacrificial layer to form the second contact sub-hole to expose the protection layer.

Optionally, prior to the step of removing at least part of the remaining interlayer sacrificial layer, the method further comprises:

forming an isolation layer on sidewall of the first contact sub-hole.

Optionally, the method further includes:

when removing the protection layer exposed in the contact hole, etching the interlayer insulating layer exposed in the second contact sub-hole to form a third contact sub-hole, which has a larger size than that of the second contact sub-hole along a stacking direction of the stacked layers.

Optionally, the gate structure comprises a high-dielectric-constant dielectric layer and a gate layer, the high-dielectric-constant dielectric layer is positioned between the gate layer and the interlayer insulating layer and between the gate layer and the protection layer.

The step of removing the protection layer exposed in the contact hole to expose the gate structure comprises:

removing the protection layer exposed in the contact hole to expose the high-dielectric-constant dielectric layer; and

removing the high-dielectric-constant dielectric layer exposed in the contact hole to expose the gate layer.

Optionally, the contact structure comprises an adhesive layer and a conductive layer.

The step of forming the contact structure in the contact hole comprises:

forming the adhesive layer in the contact hole in such a way that the adhesive layer is positioned on sidewall of the first contact sub-hole and filled in the second contact sub-hole to be connected with the gate layer; and

forming the conductive layer surrounded by the adhesive layer in the first contact sub-hole.

Optionally, the substrate comprises a core region and a connection region.

The gate structure is positioned in the core region and the connection region, the remaining interlayer sacrificial layer is positioned in the connection region.

Accordingly, the present disclosure further provides a semiconductor device, which comprises:

a semiconductor layer;

a stack structure on the semiconductor layer, the stack structure comprising interlayer material layers and interlayer insulating layers which are alternately stacked, the interlayer material layer comprising a gate structure and an interlayer sacrificial layer;

a protection layer between the gate structure and the interlayer sacrificial layer;

a contact structure extending from a side of the stack structure facing away from the semiconductor layer into the interlayer sacrificial layer and connected with the gate structure.

Optionally, the gate structure comprises a gate layer and a high-dielectric-constant dielectric layer.

The high-dielectric-constant dielectric layer is positioned between the gate layer and the interlayer insulating layer and between the gate layer and the protection layer, the contact structure is connected with the gate layer.

Optionally, the contact structure comprises a conductive layer and an adhesive layer.

The conductive layer extends from the side of the stack structure facing away from the semiconductor layer to the interlayer sacrificial layer, the adhesive layer is disposed around the conductive layer and connected with the gate layer.

Optionally, the adhesive layer comprises a first adhesive sub-layer and a second adhesive sub-layer.

The first adhesive sub-layer is positioned on the second adhesive sub-layer and is disposed around the conductive layer, the second adhesive sub-layer is disposed in a same layer as the gate layer and connected with the gate layer.

Optionally, the second adhesive sub-layer has a greater thickness than that of the gate structure.

Optionally, the interlayer insulating layer in contact with the second adhesive sub-layer has a smaller thickness than that of the interlayer insulating layer not in contact with the second adhesive sub-layer.

Optionally, the semiconductor device further comprises an isolation layer.

The isolation layer is disposed around the first adhesive sub-layer.

Optionally, the semiconductor layer comprises a core region and a connection region.

The gate structure is positioned in the core region and the connection region, the interlayer sacrificial layer is positioned in the connection region.

Accordingly, the present disclosure further provides a memory, which comprises:

a memory array comprising the above semiconductor device;

a peripheral device bonded to the memory array.

Accordingly, the present disclosure further provides a memory system, which comprises:

the above memory;

a controller connected with the memory.

The examples of the present disclosure provide a semiconductor device and a manufacturing method thereof, a memory and a memory system, in which after part of an interlayer sacrificial layer is removed to form a gate gap, a protection layer and a gate structure can be sequentially formed in the gate gap, so that the protection layer is removed to form a contact structure connected with the gate structure in the contact hole after a contact hole is formed. Due to provision of the protection layer, the gate structure can be prevented from being etched when the contact hole is formed, so that the loss of the gate structure is avoided, the risk of electric leakage is reduced, and the reliability of the memory is improved.

To sum up, although the present disclosure has been disclosed by the preferred examples, the above preferred examples are not intended to limit the present disclosure, those skilled in the art may make various changes and embellishments without departing from the spirit and scope of the present disclosure. Therefore, the protection scope of the present disclosure is defined by the claims.

What is claimed is:

1. A method of manufacturing a semiconductor device, comprising:
providing a substrate and stacked layers on the substrate, the stacked layers comprising interlayer sacrificial layers and interlayer insulating layers which are alternately stacked;
removing part of the interlayer sacrificial layers to form a gate gap;
sequentially forming a protection layer and a gate structure in the gate gap;
forming a contact hole extending from a side of the stacked layers facing away from the substrate into a remaining interlayer sacrificial layer and exposing the protection layer;
removing the protection layer exposed in the contact hole to expose the gate structure; and
forming a contact structure in the contact hole so that the contact structure is connected with the gate structure.

2. The method of claim 1, wherein sequentially forming the protection layer and the gate structure in the gate gap comprises:
forming the protection layer at the remaining interlayer sacrificial layer exposed in the gate gap; and
filling the gate structure in the gate gap.

3. The method of claim 2, wherein forming the protection layer at the remaining interlayer sacrificial layer exposed in the gate gap comprises oxidizing the remaining interlayer sacrificial layer exposed in the gate gap to form the protection layer.

4. The method of claim 1, wherein the contact hole comprises a first contact sub-hole and a second contact sub-hole communicated with each other and wherein forming the contact hole comprises:
forming the first contact sub-hole extending from the side of the stacked layers facing away from the substrate to the remaining interlayer sacrificial layer; and
removing at least part of the remaining interlayer sacrificial layer to form the second contact sub-hole to expose the protection layer.

5. The method of claim 4, wherein prior to removing at least part of the remaining interlayer sacrificial layer, further comprising forming an isolation layer on sidewall of the first contact sub-hole.

6. The method of claim 4 further comprising when removing the protection layer exposed in the contact hole, etching the interlayer insulating layers exposed in the second contact sub-hole to form a third contact sub-hole, which has a larger size than that of the second contact sub-hole along a stacking direction of the stacked layers.

7. The method of claim 4 wherein the gate structure comprises a high-dielectric-constant dielectric layer and a gate layer, the high-dielectric-constant dielectric layer positioned between the gate layer and the interlayer insulating layers and between the gate layer and the protection layer, and wherein removing the protection layer exposed in the contact hole to expose the gate structure comprises:
removing the protection layer exposed in the contact hole to expose the high-dielectric-constant dielectric layer; and
removing the high-dielectric-constant dielectric layer exposed in the contact hole to expose the gate layer.

8. The method of claim 7, wherein the contact structure comprises an adhesive layer and a conductive layer and wherein forming the contact structure in the contact hole comprises:
forming the adhesive layer in the contact hole so that the adhesive layer is positioned on sidewall of the first contact sub-hole and filled in the second contact sub-hole to be connected with the gate layer; and
forming the conductive layer surrounded by the adhesive layer in the first contact sub-hole.

9. The method of claim 1, wherein substrate comprises a core region and a connection region, and wherein the gate structure is positioned in the core region and the connection region and the remaining interlayer sacrificial layer is positioned in the connection region.

10. A semiconductor device comprising:
a semiconductor layer;
a stack structure on the semiconductor layer, the stack structure comprising interlayer material layers and interlayer insulating layers which are alternately stacked, the interlayer material layer comprising a gate structure and an interlayer sacrificial layer;
a protection layer between the gate structure and the interlayer sacrificial layer; and
a contact structure extending from a side of the stack structure facing away from the semiconductor layer into the interlayer sacrificial layer and connected with the gate structure.

11. The semiconductor device of claim 10, wherein the gate structure comprises a gate layer and a high-dielectric-constant dielectric layer; and
the high-dielectric-constant dielectric layer is positioned between the gate layer and the interlayer insulating layers and between the gate layer and the protection layer, the contact structure being connected with the gate layer.

12. The semiconductor device of claim 11, wherein the contact structure comprises a conductive layer and an adhesive layer; and
the conductive layer extends from the side of the stack structure facing away from the semiconductor layer to the interlayer sacrificial layer, the adhesive layer is disposed around the conductive layer and connected with the gate layer.

13. The semiconductor device of claim 12, wherein the adhesive layer comprises a first adhesive sub-layer and a second adhesive sub-layer; and
the first adhesive sub-layer is positioned on the second adhesive sub-layer and disposed around the conductive layer, and the second adhesive sub-layer is disposed in a same layer as the gate layer and connected with the gate layer.

14. The semiconductor device of claim 13, wherein the second adhesive sub-layer has a greater thickness than that of the gate structure.

15. The semiconductor device of claim 13, wherein the interlayer insulating layers in contact with the second adhesive sub-layer has a smaller thickness than that of the interlayer insulating layers not in contact with the second adhesive sub-layer.

16. The semiconductor device of claim 13, wherein the semiconductor device further comprises an isolation layer disposed around the first adhesive sub-layer.

17. The semiconductor device of claim 10, wherein the semiconductor layer comprises a core region and a connection region; and
the gate structure is positioned in the core region and the connection region, and the interlayer sacrificial layer is positioned in the connection region.

18. A memory system comprising:
a memory array comprising:
a semiconductor layer;
a stack structure on the semiconductor layer, the stack structure comprising interlayer material layers and interlayer insulating layers which are alternately stacked, the interlayer material layer comprising a gate structure and an interlayer sacrificial layer;
a protection layer between the gate structure and the interlayer sacrificial layer; and
a contact structure extending from a side of the stack structure facing away from the semiconductor layer into the interlayer sacrificial layer and connected with the gate structure; and
a controller connected with the memory array.
